(19) United States
(12) Patent Application Publication
(10) Pub. No.: US 2026/0324431 A1
(43) Pub. Date: Oct. 15, 2026

(54) PACKAGING STRUCTURE OF CHP CARRIER PLATE

(71) Applicant: KINSUS INTERCONNECT TECHNOLOGY CORP., Taoyuan City (TW)

(72) Inventors: Ting-Hao LIN, Taoyuan City (TW); Chiao-Cheng CHANG, Taoyuan City (TW); Chou-Ying LIN, Taoyuan City (TW); Chien-Wei CHANG, Taoyuan City (TW)

(21) Appl. No.: 19/284,292

(22) Filed: Jul. 29, 2025

(30) Foreign Application Priority Data
Apr. 14, 2025 (TW) 114203673

(51) Int. Cl. H01L 23/00; H01L 23/15; H01L 23/538

(52) U.S. Cl. CPC H10W 42/121; H10W 70/611; H10W 70/635; H10W 70/692

(57) ABSTRACT

A packaging structure of a chip carrier plate includes a chip carrier plate and a rigid frame. The rigid frame is mounted on an outer frame of the chip carrier plate through an adhesive layer. The chip carrier plate includes a substrate, a plurality of ceramic plates, a plurality of metal columns, a resin layer, a first circuit layer, and a second circuit layer. The substrate has a first through hole. The ceramic plate has a second through hole. The metal column is filled in the second through hole. An opening is provided on the resin layer. The first circuit layer is on a part of the resin layer and in the opening, and is connected to the metal column. The second circuit layer is on a part of the lower surface of the substrate and in the first through hole, and is connected to the metal column.

### CROSS-REFERENCE TO RELATED APPLICATION

This non-provisional application claims priority under 35 U.S.C. § 119(a) to Patent Application No. 114203673 filed in Taiwan, R.O.C. on Apr. 14, 2025, the entire contents of which are hereby incorporated by reference.

### BACKGROUND

### Technical Field

This application relates to the field of chip packaging, and to a packaging structure of a chip carrier plate.

### Related Art

With development of various chips, various chips of different sizes and different pin gaps are mounted on a circuit board. Therefore, semiconductor packaging introduces an intermediary plate, which simplifies a size of the circuit board. Different chips are mounted through the intermediary plate and then soldered to the circuit board. For a requirement of large-area splicing of vertical and horizontal cross sections, a largest challenge includes a thickness, flatness, and heat stability of a chip carrier plate.

Currently, a ceramic plate or another rigid substrate is introduced as a core, to resolve problems of the thickness, the flatness, and the heat stability. However, a layer is usually added to the ceramic plate for redistribution of circuits. A redistribution layer is usually formed on a resin layer. When the resin layer is used for a long time, the resin layer may be excessively hot, resulting in deformation. This may result in dislodgement of welds, and then result in electrical defects.

### SUMMARY

A packaging structure of a chip carrier plate is provided. The packaging structure of the chip carrier plate includes a chip carrier plate and a rigid frame. The rigid frame is mounted on an outer frame of the chip carrier plate through an adhesive layer. The chip carrier plate includes a substrate, a plurality of ceramic plates, a plurality of metal columns, a resin layer, a first circuit layer, and a second circuit layer.

The substrate includes an upper surface and a lower surface, and the substrate has a plurality of first through holes penetrating through the upper surface and the lower surface. The ceramic plates are disposed on the upper surface of the substrate, and a plurality of second through holes are provided on the ceramic plates and each of the second through holes penetrates through a first surface and a second surface of each ceramic plate. The metal columns are respectively filled in the second through holes. The resin layer is on the upper surface of the substrate and the ceramic plates to cover the ceramic plates and the upper surface of the substrate, a plurality of openings are provided on the resin layer, and the openings respectively correspond to the second through holes. The first circuit layer is on a part of a surface of the resin layer and in the openings, and is connected to the metal columns. The second circuit layer is on a part of the lower surface of the substrate and in the first through holes, and is connected to the metal columns.

In some embodiments, the chip carrier plate includes a dummy region, and the dummy region is at an outer periphery of the chip carrier plate.

More specifically, in some embodiments, the rigid frame includes two first supports and two second supports, the two first supports are arranged in parallel, the two second supports are arranged in parallel, two ends of the second support are respectively connected to the two first supports, and the rigid frame is integrally formed.

More specifically, in some embodiments, the rigid frame includes two first supports and two second supports, the two first supports are arranged in parallel, the two second supports are arranged in parallel, and two ends of the second support are respectively connected to the two first supports.

Further, in some embodiments, the rigid frame further includes a plurality of abutting portions, and the abutting portions extend out from the rigid frame and abut against the dummy region of the chip carrier plate.

More specifically, in some embodiments, the abutting portions respectively extend out from each first support and each second support.

More specifically, in some embodiments, the abutting portions are respectively at intersections between each first support and each second support.

In some embodiments, the rigid frame is selected from a group formed by a ceramic material, a carbon fiber material, and a graphite fiber material.

In some embodiments, a Young's modulus of the rigid frame is greater than or equal to 250 GPa, and a coefficient of thermal expansion of the rigid frame is less than or equal to 10×10⁻⁶/K.

In some embodiments, a thickness of the ceramic plate ranges from 200 μm to 1000 μm, and a height of the rigid frame is greater than a thickness of the chip carrier plate.

As described in the foregoing embodiments, the chip carrier plate is limited by using the rigid frame, so that expansion and contraction of the chip carrier plate is limited, thereby reducing possible deformation. In addition, a heat dissipation effect is provided, and heat stability of the chip carrier plate is further maintained, thereby improving a service life of an entire product.

### BRIEF DESCRIPTION OF THE DRAWINGS

FIG. 1 is an exploded view of a first embodiment of a packaging structure of a chip carrier plate;

FIG. 2 is a partial cross-sectional view of a first embodiment of a packaging structure of a chip carrier plate;

FIG. 3 is a three-dimensional view of a second embodiment of a packaging structure of a chip carrier plate;

FIG. 4 is a three-dimensional view of a third embodiment of a packaging structure of a chip carrier plate; and

FIG. 5 is a three-dimensional view of a fourth embodiment of a packaging structure of a chip carrier plate.

### DETAILED DESCRIPTION

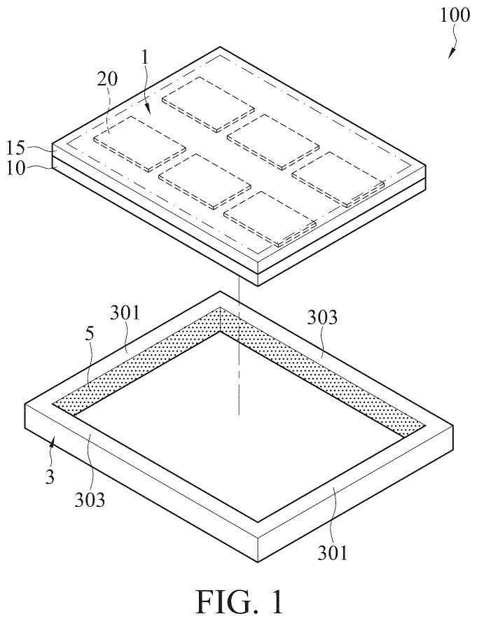

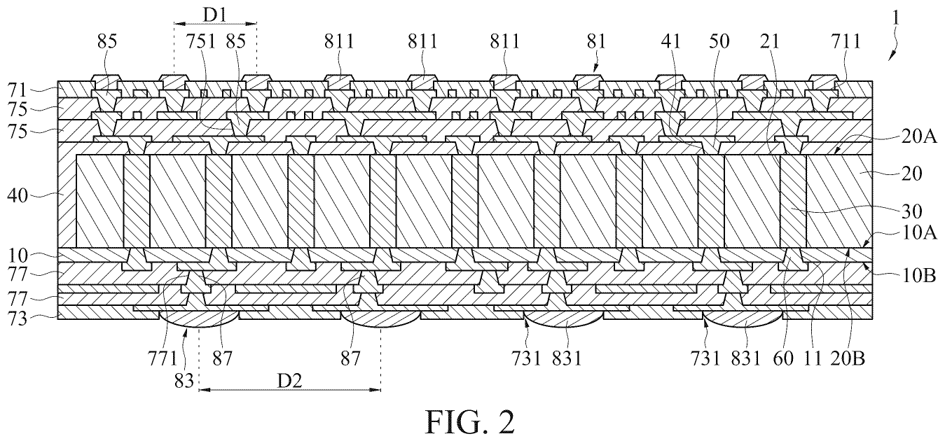

FIG. 1 is an exploded view of a first embodiment of a packaging structure of a chip carrier plate, and FIG. 2 is a partial cross-sectional view of a first embodiment of a packaging structure of a chip carrier plate. As shown in FIG. 1 and FIG. 2, a packaging structure 100 of a chip carrier plate includes a chip carrier plate 1 and a rigid frame 3. The rigid frame 3 is mounted on an outer frame of the chip carrier plate 1 through an adhesive layer 5. The rigid frame 3 provides heat conduction of the chip carrier plate 1, and is also configured to limit expansion and contraction of the chip carrier plate 1, to ensure stability of the chip carrier plate 1 and a chip on the chip carrier plate 1 during use.

As shown in FIG. 1 and FIG. 2, the chip carrier plate 1 includes a substrate 10, a plurality of ceramic plates 20, a plurality of metal columns 30, a resin layer 40, a first circuit layer 50, and a second circuit layer 60. The ceramic plate 20 may provide a low coefficient of thermal expansion, and may provide good flatness at a thin thickness. A Young's modulus of the rigid frame 3 is greater than or equal to 250 GPa, and a coefficient of thermal expansion of the rigid frame 3 is less than or equal to 10×10⁻⁶/K, and the rigid frame 3 may be made of a ceramic material, a carbon fiber material, a graphite fiber material, or a composite material thereof. To improve a heat dissipation effect, for the adhesive layer 5, a high-strength heat-conductive adhesive may be used, or a heat-conductive material such as epoxy resin with ceramic particles may be added.

The substrate 10 includes an upper surface 10A and a lower surface 10B, and the substrate 10 has a plurality of first through holes 11 penetrating through the upper surface 10A and the lower surface 10B. The ceramic plates 20 are disposed on the upper surface 10A of the substrate 10, and a plurality of second through holes 21 are provided on the ceramic plates 20 and each of the of second through holes 21 penetrates through a first surface 20A and a second surface 20B of each ceramic plate 20. The metal columns 30 are respectively filled in the second through holes 21. The resin layer 40 is on the upper surface 10A of the substrate 10 and the ceramic plates 20 to cover the ceramic plates 20 and the upper surface 10A of the substrate 10, a plurality of openings 41 are provided on the resin layer 40, and the openings 41 respectively correspond to the second through holes 21. The first circuit layer 50 is on a part of a surface of the resin layer 40 and in the openings 41, and is connected to the metal columns 30. The second circuit layer 60 is on a part of the lower surface 10B of the substrate 10 and in the first through holes 11, and is connected to the metal columns 30.

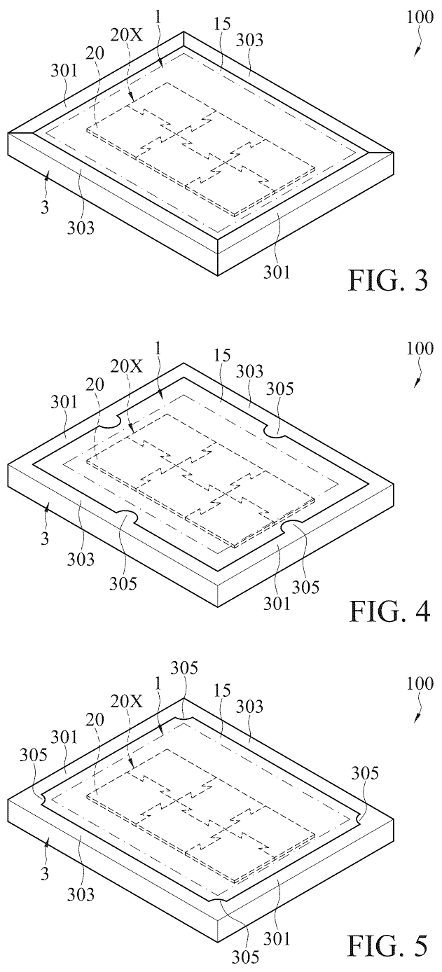

FIG. 3 is a three-dimensional view of a second embodiment of a packaging structure of a chip carrier plate. As shown in FIG. 3, and also referring to FIG. 1, the ceramic plates 20 may be dispersed on the substrate 10 according to a requirement of the chip, or the ceramic plates 20 may be spliced to each other, to form a larger ceramic plate assembly 20X. In addition, the rigid frame 3 may be integrally formed, or may be assembled and formed. Further, a thickness of the ceramic plate 20 ranges from 200 μm to 1000 μm, for example, 400 μm to 650 μm, and a height of the rigid frame 3 is greater than a thickness of the chip carrier plate 1.

FIG. 4 is a three-dimensional view of a third embodiment of a packaging structure of a chip carrier plate, and FIG. 5 is a three-dimensional view of a fourth embodiment of a packaging structure of a chip carrier plate. As shown in FIG. 4 and FIG. 5, the chip carrier plate 1 includes a dummy region 15, and the dummy region 15 is at an outer periphery of the entire chip carrier plate 1. The rigid frame 3 includes two first supports 301 and two second supports 303, the two first supports 301 are arranged in parallel, the two second supports 303 are arranged in parallel, and two ends of the second support are respectively connected to the two first supports 301. The rigid frame 3 further includes a plurality of abutting portions 305, and the abutting portions 305 extend out from the rigid frame 3 and abut against the dummy region 15 of the chip carrier plate 1.

As shown in FIG. 4, the abutting portions 305 respectively extend out from each first support 301 and each second support 303. A symmetrical design is used, but an asymmetrical configuration may be actually used. As shown in FIG. 5, the abutting portions 305 are respectively at intersections between each first support 301 and each second support 303.

Referring to FIG. 2 again, the chip carrier plate 1 further includes a first anti-soldering lacquer layer 71, a first pad layer 81, a second anti-soldering lacquer layer 73, and a second pad layer 83. The first anti-soldering lacquer layer 71 is on the resin layer 40, and a plurality of first pad openings 711 are provided. The first pad layer 81 is filled in the first pad openings 711, and is electrically connected to the first circuit layer 50. The second anti-soldering lacquer layer 73 is on the lower surface 10B of the substrate 10, and a plurality of second pad openings 731 are provided. The second pad layer 83 is filled in the second pad openings 731, and is electrically connected to the second circuit layer 60. The first pad layer 81 includes a plurality of first pads 811, and the first pads 811 protrude from the first anti-soldering lacquer layer 71. The second pad layer 83 includes a plurality of second pads 831, the second pads 831 protrude from the second anti-soldering lacquer layer 73, and a first spacing D1 between the first pads 811 is less than a second spacing D2 between the second pads 831. More specifically, the chip carrier plate 1 is used as an interconnection between the chip and a circuit board.

Further, in some embodiments, the chip carrier plate 1 further includes a first protection layer 75, a first redistribution layer 85, a second protection layer 77, and a second redistribution layer 87. The first protection layer 75 is between the resin layer 40 and the first anti-soldering lacquer layer 71, covers the first circuit layer 50, and has a plurality of first openings 751. The first redistribution layer 85 is on a part of the first protection layer 75 and is filled in the first openings 751, and connects the first circuit layer 50 and the first pad layer 81. The second protection layer 77 is between the lower surface 10B of the substrate 10 and the second anti-soldering lacquer layer 73, covers the second circuit layer 60, and has a plurality of second openings 771. The second redistribution layer 87 is on a part of the second protection layer 77 and is filled in the second openings 771, and connects the second circuit layer 60 and the second pad layer 83.

More specifically, in some embodiments, positions of the first openings 751 respectively correspond to the first pad openings 711, and positions of the second openings 771 respectively correspond to the second pad openings 731. The first protection layer 75, the first redistribution layer 85, the second protection layer 77, and the second redistribution layer 87 may cooperate with line allocation, and may have one or more layers.

In conclusion, the chip carrier plate 1 is limited by using the rigid frame 3, so that expansion and contraction of the chip carrier plate 1 is limited, thereby reducing possible deformation. In addition, a heat dissipation effect is provided, and heat stability of the chip carrier plate 1 is further maintained, thereby improving a service life of an entire product.

Although the application has been described in considerable detail with reference to certain preferred embodiments thereof, the application is not for limiting the scope of the invention. Persons having ordinary skill in the art may make various modifications and changes without departing from the scope and spirit of the application. Therefore, the scope of the appended claims should not be limited to the description of the preferred embodiments described above.

What is claimed is:

1. A packaging structure of a chip carrier plate, comprising:
a chip carrier plate, comprising:
a substrate comprising an upper surface and a lower surface, wherein the substrate has a plurality of first through holes penetrating through the upper surface and the lower surface;
a plurality of ceramic plates disposed on the upper surface of the substrate, a plurality of second through holes being provided on the ceramic plates and wherein each of the second through holes penetrates through a first surface and a second surface of each ceramic plate;
a plurality of metal columns, respectively filled in the second through holes;
a resin layer on the upper surface of the substrate and the ceramic plates to cover the ceramic plates and the upper surface of the substrate, a plurality of openings being provided on the resin layer, and the openings respectively corresponding to the second through holes;
a first circuit layer on a part of a surface of the resin layer and in the openings, and connected to the metal columns; and
a second circuit layer on a part of the lower surface of the substrate and in the first through holes, and connected to the metal columns; and
a rigid frame mounted on an outer frame of the chip carrier plate through an adhesive layer.

2. The packaging structure of the chip carrier plate according to claim 1, wherein the chip carrier plate comprises a dummy region, and the dummy region is at an outer periphery of the chip carrier plate.

3. The packaging structure of the chip carrier plate according to claim 2, wherein the rigid frame comprises two first supports and two second supports, the two first supports are arranged in parallel, the two second supports are arranged in parallel, two ends of the second support are respectively connected to the two first supports, and the rigid frame is integrally formed.

4. The packaging structure of the chip carrier plate according to claim 2, wherein the rigid frame comprises two first supports and two second supports, the two first supports are arranged in parallel, the two second supports are arranged in parallel, and two ends of the second support are respectively connected to the two first supports.

5. The packaging structure of the chip carrier plate according to claim 3, wherein the rigid frame further comprises a plurality of abutting portions, and the abutting portions extend out from the rigid frame and abut against the dummy region of the chip carrier plate.

6. The packaging structure of the chip carrier plate according to claim 5, wherein the abutting portions respectively extend out from each first support and each second support.

7. The packaging structure of the chip carrier plate according to claim 5, wherein the abutting portions are respectively at intersections between each first support and each second support.

8. The packaging structure of the chip carrier plate according to claim 4, wherein the rigid frame further comprises a plurality of abutting portions, and the abutting portions extend out from the rigid frame and abut against the dummy region of the chip carrier plate.

9. The packaging structure of the chip carrier plate according to claim 8, wherein the abutting portions respectively extend out from each first support and each second support.

10. The packaging structure of the chip carrier plate according to claim 8, wherein the abutting portions are respectively at intersections between each first support and each second support.

11. The packaging structure of the chip carrier plate according to claim 1, wherein the rigid frame is selected from a group comprising a ceramic material, a carbon fiber material, and a graphite fiber material.

12. The packaging structure of the chip carrier plate according to claim 1, wherein a Young's modulus of the rigid frame is greater than or equal to 250 GPa, and a coefficient of thermal expansion of the rigid frame is less than or equal to 10×10⁻⁶/K.

13. The packaging structure of the chip carrier plate according to claim 1, wherein a thickness of the ceramic plate ranges from 200 μm to 1000 μm, and a height of the rigid frame is greater than a thickness of the chip carrier plate.
